(19) United States
(12) Patent Application Publication
(10) Pub. No.: US 2007/0111529 A1
(43) Pub. Date: May 17, 2007

(54) PLASMA ETCHING METHOD

(75) Inventor: Masaru NISHINO, Beverly, MA (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku, Tokyo (JP)

(21) Appl. No.: 11/561,160

(22) Filed: Nov. 17, 2006

Related U.S. Application Data
(60) Provisional application No. 60/750,392, filed on Dec. 15, 2005.

(30) Foreign Application Priority Data
Nov. 17, 2005 (JP) 2005-332896

(51) Int. Cl. H01L 21/302

(52) U.S. Cl. 438/710

(57) ABSTRACT

In a plasma etching method for etching a target object by using a plasma of a processing gas in a processing chamber of a plasma processing apparatus, the target object includes an etching target film and a porous Low-k film formed above the etching target film. The processing gas contains CO₂ and a fluorocarbon compound made up of fluorine and carbon in which the number of carbon atom is 2 or less in a molecule, but does not contains a hydrofluorocarbon compound made up of carbon, fluorine and hydrogen.

### FIELD OF THE INVENTION

The present invention relates to a plasma etching method; and, more particularly, to a plasma etching method for etching an etching target film formed on a target object by using a plasma during a manufacturing process of a semiconductor device.

### BACKGROUND OF THE INVENTION

In a manufacturing process of a semiconductor wafer having a multilayer wiring structure, for example, when an interlayer insulating film is etched to form recesses such as wiring connection holes or the like, a stopper film such as a silicon nitride film or a silicon carbide film is formed as a base film on a lower wiring. In order to electrically connect wirings, such a stopper film is removed by an etching at a final step of forming the recesses.

As for a method for etching a silicon nitride film or a silicon carbide film, there has been proposed a method for performing a plasma etching process by using a fluorocarbon gas (CF-based gas) containing carbon and fluorine in a molecule and a hydrofluorocarbon gas (CHF-based gas) containing carbon, hydrogen and fluorine in a molecule in order to obtain an etching selectivity of an organic SiO₂ film to an SiN film serving as a base film (see, e.g., Japanese Patent Laid-open Application No. 2003-234337).

Further, there has been proposed another method for performing a plasma etching process by using a fluorocarbon gas and a hydrogen source such as CH₂F₂, CH₃F or the like in order to anisotropically etch a silicon nitride film in a multilayer structure (see, e.g., Japanese Patent Laid-open Application No. H11-102896) . Furthermore, there has been suggested still another method for performing a plasma etching process by using a fluorocarbon gas and a hydrogen source such as CHF₃, CH₂F₂, CH₃F or the like in order to maintain a high selectivity of silicon nitride film to a mask layer in forming a trench of a high aspect ratio in the silicon nitride film (see, e.g., Japanese Patent Laid-open Application No. 2000-340552).

A current design rule of a large scale integrated circuit (LSI) is expected to change from 90 nm to 65 nm and further to 45 nm, which leads to a more compact wiring structure. With the more compact wiring structure, it is required to avoid a signal delay caused by an electric capacity generated in an insulating layer between the wirings. Accordingly, there is being developed an interlayer insulating film made of a Low-k material to prevent the signal delay. As for the interlayer insulating film made of a Low-k material, there is suggested a porous Low-k film having a smaller dielectric constant and a lower resistance than the conventional one. Although the porous Low-k film has a low dielectric constant, its strength and etching resistance are inferior due to the presence of pores therein.

When plasma etching the base film such as the silicon nitride film or the silicon carbide film, it is needed to secure an etching selectivity thereof to an uppermost etching mask film.

Moreover, an etching rate may deteriorate when a polymer formed by a reaction between components of a processing gas and those of the film is adhered to a surface of a target object during an etching process. Therefore, it is required to suppress the formation and adhesion of the polymer.

Further, device characteristics are damaged when there occurs a side etching in which the base film as an etching target film, such as the silicon nitride film or the silicon carbide film, is etched in a horizontal direction. Hence, it is also required to prevent the side etching.

Furthermore, in case the porous Low-k film is used for an interlayer insulating film formed above the base film such as the silicon nitride film or the silicon carbide film, the porous Low-k film is oxidized and a plasma damage is likely to occur thereat. Consequently, if a hydrofluoric acid treatment is carried out in a next step, the oxidized portion is removed and, thus, the damage appears. In addition, a large number of cracks are formed on a surface of the porous Low-k film due to an exposure to the plasma, thereby making the surface rough.

The deterioration of the porous Low-k film serving as an interlayer insulating film leads to a decrease in reliability of the semiconductor device. As a result, the plasma etching process needs to be performed under the condition that no damage occurs at the porous Low-k film.

When the plasma etching process is performed on the target object having the porous Low-k film formed above the etching target film, it is extremely difficult to select plasma etching conditions compared with a case of performing the plasma etching process on a target object having no porous Low-k film. So far there has not been found a condition capable of resolving all the aforementioned problems.

### SUMMARY OF THE INVENTION

It is, therefore, an object of the present invention to provide a plasma etching method capable of, when a plasma etching process is performed on the silicon nitride film or a silicon carbide film of a target object having a porous Low-k film as an interlayer insulating film formed above a base film such as the silicon nitride film or the silicon carbide film, securing an etching selectivity to a hard mask film, suppressing a polymer adhesion and a side etching and also suppressing a damage and a surface roughness of the porous Low-k film.

In accordance with one aspect of the invention, there is provided a plasma etching method for etching a target object by using a plasma of a processing gas in a processing chamber of a plasma processing apparatus, wherein the target object includes an etching target film and a porous Low-k film formed above the etching target film, and wherein the processing gas is devoid of a hydrofluorocarbon compound formed of carbon, fluorine and hydrogen and contains CO₂ and a fluorocarbon compound formed of fluorine and carbon, the number of carbon being smaller than or equal to two.

Preferably, the fluorocarbon compound is CF₄.

Preferably, a flow rate ratio of the fluorocarbon compound and CO₂ ranges from 3:1 to 10:1.

Preferably, the porous Low-k film is an inorganic Low-k film having a dielectric constant of 2.0 to 2.7.

Preferably, the target etching film is etched by using as a mask a hard mask film formed above the porous Low-k film.

Preferably, the target etching film is a silicon nitride film or a silicon carbide film.

Furthermore, an etching selectivity of the target etching film to the hard mask film is preferably greater than two.

In addition, adhesion films may be formed between the target etching film and the porous Low-k film and between the porous Low-k film and the hard mask film, respectively.

In accordance with another aspect of the invention, there is provided a control program, operating on a computer, for controlling the plasma processing apparatus to perform the plasma etching method of the first aspect of the present invention.

In accordance with still another aspect of the invention, there is provided a computer readable storage medium for storing therein a control program operating on a computer, wherein the control program controls the plasma processing apparatus to perform the plasma etching method of the first aspect of the present invention.

In accordance with the plasma processing method of the preset invention, a plasma etching process is performed on a target object having an etching target film and a porous Low-k film formed above the target etching film by using a processing gas containing CO₂ and a fluorocarbon compound made up of fluorine and carbon wherein the number of carbon atom is 2 or less in a molecule but not containing a hydrofluorocarbon compound made up of carbon, fluorine and hydrogen. Accordingly, it is possible to perform the etching process while securing a high etching selectivity to the hard mask film, and suppressing the adhesion of polymer, the side etching, the damage to the porous Low-k film and the surface roughness of the porous Low-k film.

Hence, the plasma processing method of the present invention can be appropriately employed as an etching process in manufacturing a semiconductor device having a multilayer wiring structure containing a porous Low-k film as an interlayer insulating film, for example.

### BRIEF DESCRIPTION OF THE DRAWINGS

The above and other objects and features of the present invention will become apparent from the following description of preferred embodiments, given in conjunction with the accompanying drawings, in which:

FIG. 1 schematically shows a plasma processing apparatus of the present invention;

FIG. 2 provides a schematic diagram of a cross sectional structure of a wafer before it is plasma etched;

FIG. 3 presents a schematic diagram of a cross sectional structure of the wafer which is being plasma etched;

FIG. 4 represents a schematic diagram of a cross sectional structure of the wafer after it has been plasma etched;

FIG. 5 offers, as an example of a damascene process, a schematic diagram of a cross sectional structure of a wafer which is being plasma etched; and

FIG. 6 provides, as the example of the damascene process, a schematic diagram of a cross sectional structure of the wafer after it has been plasma etched.

### DETAILED DESCRIPTION OF THE PREFERRED EMBODIMENT

Hereinafter, preferred embodiments of the present invention will be described in detail with reference to the accompanying drawings.

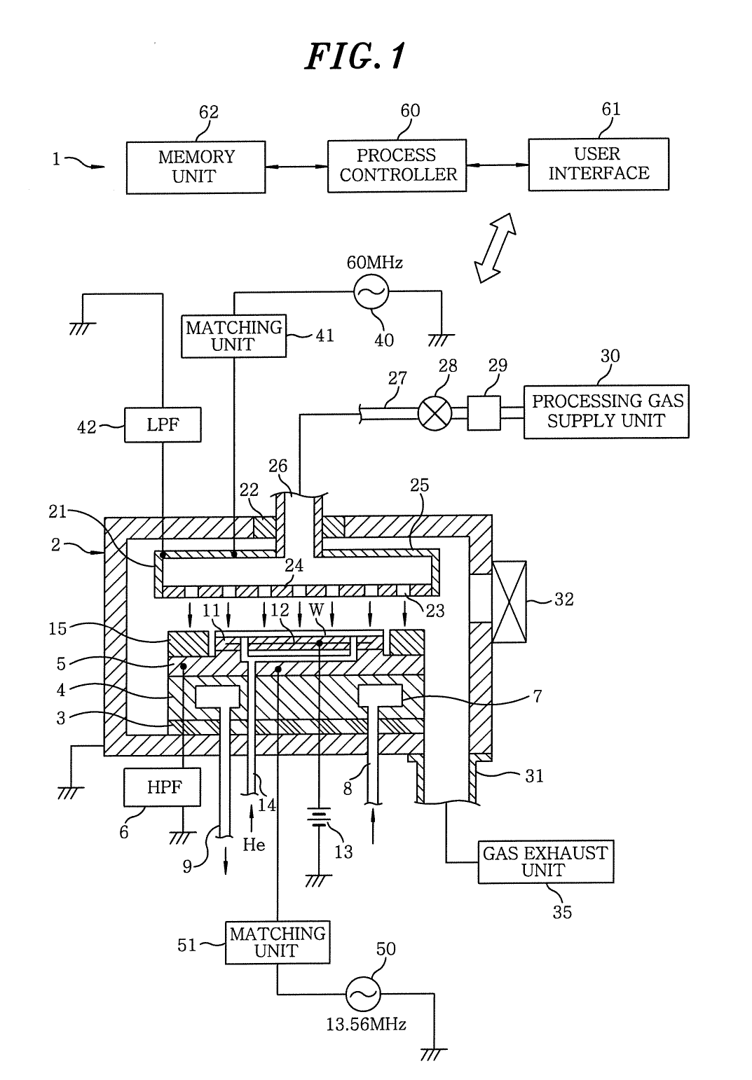

FIG. 1 schematically shows a plasma processing apparatus suitable for an etching process in accordance with a preferred embodiment of the present invention. Such a plasma processing apparatus 1 can be used as a capacitively coupled parallel plate type plasma etching apparatus having electrode plates respectively connected with high frequency power supplies, the electrode plates being arranged up and down in parallel to each other.

The plasma processing apparatus 1 includes a cylindrical chamber 2 made of aluminum having an alumite treated (anodically oxidized) surface, and the chamber 2 is grounded. Provided inside the chamber 2 is a susceptor 5 for horizontally mounting thereon as a target object a semiconductor wafer (hereinafter, referred to as “wafer”) W having predetermined films. The susceptor 5 made of, e.g., silicon serves as a lower electrode and is supported by a susceptor support 4. Further, the susceptor 5 is connected with a high pass filter (HPF) 6.

The susceptor support 4 has therein a temperature control medium passageway 7. By introducing and circulating a temperature control medium inside the temperature control medium chamber 7 via an inlet line 8 and an outlet line 9, the susceptor 5 can be controlled at a desired temperature.

The susceptor 5 is formed in a circular plate shape having a protruded upper central portion. Provided above the susceptor 5 is an electrostatic chuck 11 whose shape is approximately same as that of the wafer W. The electrostatic chuck 11 includes an electrode 12 interposed between insulating materials. By applying a DC voltage of, e.g., 1.5 kV from a DC power supply 13 connected to the electrode 12, the wafer W is electrostatically adsorbed by the Coulomb force.

A gas channel 14 for supplying a heat transfer medium, e.g., He gas, at a predetermined pressure (back pressure) to a backside of the wafer W to be processed is formed in the insulating plate 3, the susceptor support 4, the susceptor 5 and the electrostatic chuck 11. By transferring heat between the susceptor 5 and the wafer W through the heat transfer medium, the wafer W can be controlled at a predetermined temperature.

A ring-shaped focus ring 15 is provided at an upper peripheral portion of the susceptor 5 to surround the wafer W mounted on the electrostatic chuck 11. The focus ring 15 is made of, e.g., silicon, and serves to improve an etching uniformity.

Provided above the susceptor 5 is an upper electrode 21 facing the susceptor 5 in parallel thereto. The upper electrode 21 is supported at an upper portion of the chamber 2 via an insulating member 22 and has a surface facing the susceptor 5. Further, the upper electrode 21 includes an electrode plate 24 having a plurality of gas injection openings 23 and an electrode support 25 for supporting the electrode plate 24. The electrode plate 24 is made of, e.g., quartz, and the electrode support 25 is made of a conductive material, e.g., aluminum having an alumite treated surface. A gap between the susceptor 5 and the upper electrode 21 can be controlled.

A gas inlet opening 26 is provided at a central portion of the electrode support 25 of the upper electrode 21 and a gas supply line 27 is connected with the gas inlet opening 26. A processing gas supply source 30 is connected with the gas supply line 27 via a valve 28 and a mass flow controller 29, so that an etching gas for a plasma etching can be supplied from the processing gas supply source 30. As for the etching gas, it is preferable to use a gaseous mixture containing CO₂ and a fluorocarbon compound gas such as CF₄, C₂F₆ or the like. Herein, the fluorocarbon compound gas serves to perform an etching operation through a radical reaction, and CO₂ controls the radical to properly act on an etching target film. Moreover, it is also possible to add N₂, He or the like to the fluorocarbon compound gas and CO₂. Although FIG. 1 representatively illustrates a single processing gas supply source 30, there are provided a plurality of processing gas supply sources 30 which are configured to supply CO₂ and the fluorocarbon compound gas such as CF₄ into the chamber 2 while controlling flow rates thereof independently.

A gas exhaust line 31 is connected with a bottom portion of the chamber 2, and a gas exhaust unit 35 is connected with the gas exhaust line 31. Since the gas exhaust unit 35 has a vacuum pump such as a turbo-molecular pump or the like, it is configured to vacuum exhaust the inside of the chamber 2 to a predetermined depressurized atmosphere, e.g., to 1 Pa or less. A gate valve 32 is provided on a sidewall of the chamber 2. While the gate valve 32 is opened, the wafer W is transferred to/from an adjacent load-lock chamber (not shown).

A first high frequency power supply 40 is connected with the upper electrode 21, and a matching unit 41 is provided in its feeder line. Further, a low pass filter (LPF) 42 is connected with the upper electrode 21. The first high frequency power supply 40 applies a high frequency power of a frequency ranging from 50 to 150 MHz, so that a desirably dissociated high-density plasma can be formed in the chamber 2, which makes it possible to perform a plasma processing under a low pressure condition. A preferable frequency of the first high frequency power supply 40 ranges from 50 to 80 MHz, and it is typical to employ a frequency of 60 MHz or thereabout, as shown in FIG. 1.

A second high frequency power supply 50 is connected with the susceptor 5 serving as the lower electrode, and a matching unit 51 is provided in its feeder line. The second high frequency power supply 50 applies a high frequency power of a frequency ranging from several hundred KHz to less than 20 MHz, so that an appropriate ion action can be caused without inflicting damages on the wafer W. As a frequency of the second high frequency power supply 50, a frequency of, e.g., 13.56 MHz or 800 KHz is employed as shown in FIG. 1.

Each component of the plasma processing apparatus 1 is connected with a process controller 60 having a CPU and controlled by the process controller 60. The process controller 60 is connected with a user interface 61 having a keyboard, a display and the like. A process operator uses the keyboard when inputting commands for managing the plasma processing apparatus 1, and the display is used to display the operation status of the plasma processing apparatus 1.

Also, the process controller 60 is connected with a storage unit 62 for storing therein recipes including control programs (software) for implementing various processes in the plasma processing apparatus 1 under the control of the process controller 60, processing condition data and the like.

If necessary, the process controller 60 executes a recipe read from the storage unit 62 in response to an instruction from the user interface 61, thereby implementing a desired process in the plasma processing apparatus 1 under the control of the process controller 60. Further, the recipes such as the control program, the processing condition data and the like can be read from a computer-readable storage medium, e.g., a CD-ROM, a hard disk, a flexible disk, a flash memory or the like, or transmitted on-line from another device via, e.g., a dedicated line.

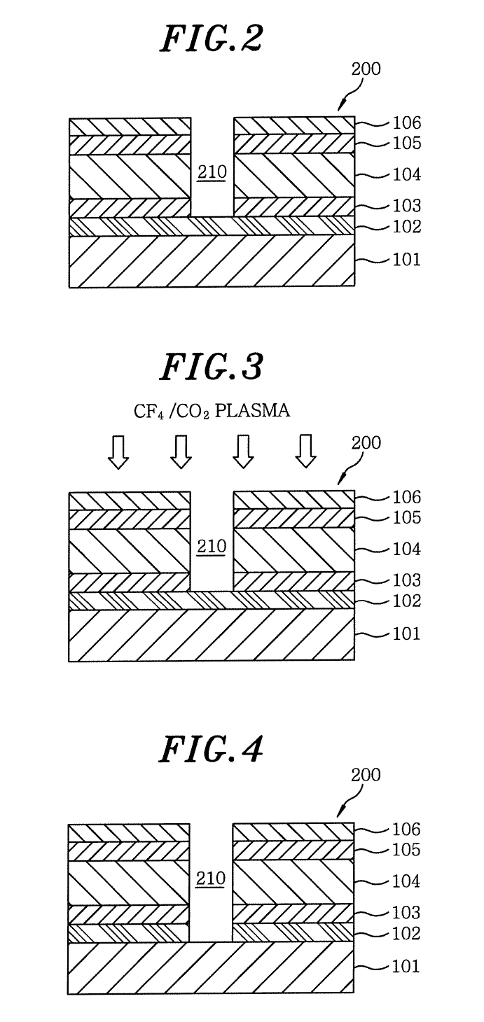

Hereinafter, there will be described a process for plasma etching a laminated structure having an etching target film by using the plasma processing apparatus 1 configured as described above with reference to FIGS. 2 to 4. FIGS. 2 to 4 show schematic enlarged vertical cross sectional views of principal parts of the wafer W to explain an outline of an etching process in accordance with the preferred embodiment of the present invention. As shown in FIG. 2, formed on a silicon substrate (not shown) of the wafer W is a laminated structure 200 including a lower wiring insulating film 101, a stopper film 102 as an etching target film, a first adhesion film 103, a porous Low-k film 104, a second adhesion film 105 and a hard mask 106, which are laminated in that order from the bottom.

The stopper film 102 is, e.g., an Si₃N₄ film, an SiC film or the like formed by a plasma CVD (Chemical Vapor Deposition) method, a spin-on-glass method or the like, and serves as an etching stopper when forming a recess 210 such as a wiring groove, a hole or the like, by an etching.

The porous Low-k film 104 is an interlayer insulating film formed by a CVD method, for example. Although the porous Low-k film 104 can be made of any material, it is preferable to use a Low-k material having a dielectric constant (k value) ranging from 2.0 to 2.7 or an inorganic Low-k material. As the Low-k material of the porous Low-k film 104, there may be used, e.g., Black Diamond 2X, Black Diamond 3 (both being trademarks of Applied Materials, Inc.), LKD (trademark of JSR Corp.), Aurora ULK, Aurora ELK (both being trademarks of ASM International N.V.), Porous Coral (trademark of Novellus Systems Inc.), an NCS (trademark of Catalyst & Chemicals Ind. Co., Ltd.) and the like.

As for the hard mask film 106 serving as an etching mask, there is used a silicon oxide film (SiO₂ film) made of TEOS (tetraethoxysilane), for example.

The first and the second adhesion film 103 and 105 are formed to improve the adhesivity of the porous Low-k film 104 vertically sandwiched therebetween. For example, a dense Low-k film, a silicon oxide film containing carbon and the like may be used as the adhesion film.

The recess 210 is formed in the laminated structure 200 to have a depth from the uppermost hard mask film 106 to the stopper film 102, by an etching based on a resist pattern formed by a photolithographic technique.

As illustrated in FIG. 3, the plasma processing apparatus 1 (see FIG. 1) performs an etching process on the laminated structure 200 having the recess 210 by using a plasma generated from CF₄ and CO₂ for example. Plasma etching conditions will be described later.

As an etching gas for removing the stopper film 102, there is used a processing gas containing CO₂ and a fluorocarbon compound gas (CF-based gas) made up of carbon and fluorine, such as CF₄, C₂F₆ or the like. In this case, if there is used a fluorocarbon compound containing a large number of carbon atoms in a molecule, a large amount of polymer as a reaction product is produced and adhered to the recess 210. Accordingly, the etching rate deteriorates and, also, the etching selectivity of the stopper film 102 to the hard mask film 106 deteriorates. Hence, the number of carbon atoms in a molecule of the fluorocarbon compound is preferably two or less.

It is important that the processing gas does not contain a hydrofluorocarbon gas (CHF-based gas) made up of carbon, fluorine and hydrogen to avoid a deterioration of the etching selectivity of the stopper film 102 to the hard mask 106.

An etching process is preferably performed under the condition that the etching selectivity, i.e., (etching rate of the stopper film 102)/(etching rate of the hard mask 106), is greater than two. In case the etching selectivity is two or less, the hard mask film 106 is etched, so that its film thickness becomes thin. Accordingly, when the hard mask film 106 is used as, e.g., a planarization stopper in a next step, it does not function properly.

The etching process can be completed when the depth of the recess 210 reaches the lower wiring insulating film 101. Consequently, as shown in FIG. 4, the stopper film 102 in the recess 210 is removed, thereby exposing the lower wiring insulating film 101.

The following is a description of specific steps of the plasma etching process in the plasma processing apparatus 1. First, the wafer W having the recess 210 is loaded from the load-lock chamber (not shown) into the chamber 2 after opening the gate valve 32 to be mounted on the electrostatic chuck 11. Next, the wafer W is electrostatically adsorbed on the electrostatic chuck 11 by applying a DC voltage from the DC power supply 13.

After the gate valve 32 is closed, the inside of the chamber 2 is vacuum exhausted to a predetermined vacuum level by using the gas exhaust unit 35. Thereafter, by opening the valve 28, for example, CO₂ and a fluorocarbon compound gas such as CF₄ is introduced as an etching gas, from the processing gas supply source 30 into a hollow portion of the upper electrode 21 via the processing gas supply line 27 and the gas inlet opening 26 while a flow rate ratio thereof is controlled to a predetermined level. Next, as indicated by arrows of FIG. 1, the etching gas is uniformly injected toward the wafer W through the gas injection openings 23 of the electrode plate 24. Herein, flow rates of CF₄/CO₂ may range from 75/25 to 600/200 mL/min (sccm) and preferably from 150/50 to 500/50 mL/min. Further, the flow rate ratio of CF₄ and CO₂ is preferably in the range of 3:1 to 10:1 in view of suppressing a side etching and a surface roughness of the porous Low-k film, securing a sufficient selectivity to the hard mask and reducing a damage and a polymer adhesion to the porous Low-k film.

A residence time of the processing gas preferably ranges from 3 to 0.17 seconds and more preferably from 1 to 0.3 seconds in view of securing a sufficient selectivity to the hard mask and reducing a damage of the Low-k film.

Herein, the residence time indicates a period of time when the etching gas contributes to the etching process inside the chamber 1. Also, the residence time τ (sec) can be obtained based on the following equation:
τ=V/S=pV/Q
wherein V (m³) indicates an effective chamber volume (i.e., a volume of a space where the processing gas is converted into a plasma) obtained by multiplying an area of the lower electrode (a total area of the wafer W and the focus ring 15 in FIG. 1) by a vertical distance between the upper and the lower electrode; S (m³/sec) represents an exhaust rate; p (Pa) indicates a pressure inside the chamber; and Q (Pa·m³/sec) represents a total flow rate of the processing gas.

The pressure inside the chamber 2 is maintained at a predetermined level of, e.g., 5 to 20 Pa and preferably 6 to 13 Pa, in view of suppressing a side etching and a surface roughness of the porous Low-k film, securing a sufficient selectivity to the hard mask and reducing a damage to the Low-k film. Further, a high frequency power of 200 to 2500 W, preferably 400 to 1500 W, is supplied from the first high frequency power supply 40 to the upper electrode 21, and a high frequency power of 100 to 1000 W, preferably 100 to 1000 W, is supplied from the second high frequency power 50 to the susceptor 5 serving as the lower electrode. Accordingly, the etching gas is converted into a plasma, thereby etching the stopper film 102. Moreover, the back pressure is preferably set to be about 2000/5000 Pa at center/edge portion of the wafer W. As for the processing temperature, it is preferable that a temperature of the wafer W (susceptor 5) is in the range of 0° C. to 40° C. in view of securing selectivity to the hard mask and suppressing the side etching and the polymer adhesion.

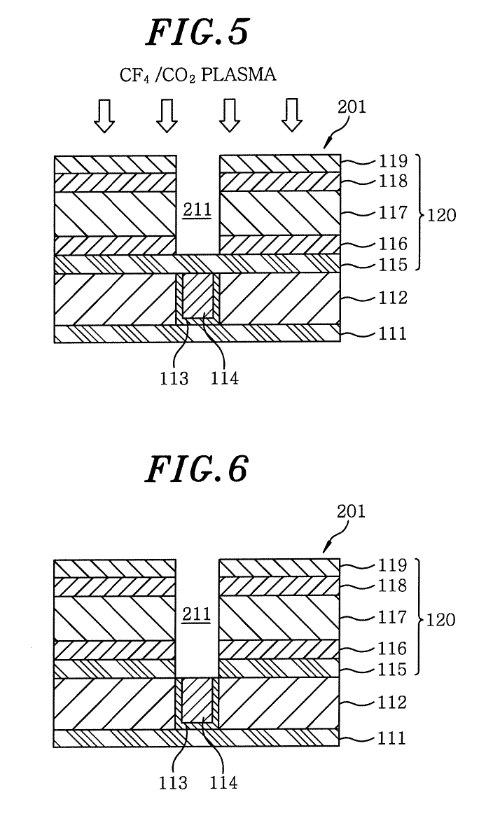

Hereinafter, a more specific example of the present invention will be described with reference to FIGS. 5 and 6. In a manufacturing process of a semiconductor device having a multilayer wiring structure, a contact plug for wiring connection, a Cu wiring or the like is generally formed by filling a metal in a via hole or a recess formed in an interlayer insulating film. Especially, as for a method for providing a Cu wiring, there is known a damascene process (single or dual damascene process). For instance, when forming the wiring by the single damascene process, a laminated structure 201 is provided on a silicon substrate (not shown) as illustrated in FIG. 5. The laminated structure 201 includes a lower wiring insulating film 112 in which a lower wiring 114 made of a metal such as Cu or the like is filled via a barrier metal 113; and a laminated interlayer insulating film 120 provided thereon, the laminated interlayer insulating film including a stopper film 115 made of SiC, SiN or the like, a first adhesion film 116, a porous Low-k film 117, a second adhesion film 118 and a hard mask film 119 laminated in that order from the bottom. A reference numeral 111 in FIGS. 5 and 6 indicates an underlayer insulating film made of SiO₂ or the like. The first and the second adhesion film 116 and 118 are provided to improve the adhesivity of the porous Low-k film 117, so that they may be omitted.

The laminated interlayer insulating film 120 has recesses 211. The recesses 211 are obtained by forming a resist pattern corresponding thereto on the interlayer insulating film 120 by using a photolithographic technique and then etching the interlayer insulating film 120 by using the resist pattern as a mask until the stopper film 115 is exposed.

Next, the stopper film 115 is etched by using the hard mask 119 as a mask to expose the lower wiring 114 made of Cu or the like, as shown in FIG. 6. At this time, the plasma processing apparatus 1 performs the plasma etching process by using the aforementioned processing gas containing CO₂ and a fluorocarbon gas.

Therefore, although not illustrated in the drawing, a barrier metal and Cu are filled in the recesses 211 through a sputtering method, a PVD (Physical Vapor Deposition) method, an electroplating method or the like and then an excess Cu is removed by a CMP (Chemical Mechanical Polishing) planarization process. During the planarization process, the hard mask film 119 serves as a stopper. In this way, a metal wiring can be formed in the semiconductor device having a multilayer wiring structure.

Hereinafter, test results for confirming effects of the present invention will be described.

By using the plasma processing apparatus 1 configured as described in FIG. 1, an etching process was performed by using the hard mask film 106 as a mask on the stopper film 102 exposed inside a plurality of recesses 210 in a laminated structure same as that shown in FIG. 2, the recesses being spaced apart from each other at predetermined intervals, and the etching characteristics were evaluated. The tests were carried out by using as an etching gas various gases properly combined as shown in Table 1.

TABLE 1

| | Damage to | | | Surface | |
|---|---|---|---|---|---|
| Test | porous | Etching | Polymer | roughness of | |
| classification | Low-k | selectivity | Suppressing | porous Low-k | side |
| (gas composition) | film | (to mask film) | effect | film | etching |
| (1)CF₄ | ◯ | X (about 1) | X | ◯ | ◯ |
| (2)CF₄/N₂ | ◯ | X (below 1) | X | ◯ | ◯ |
| (3)CF₄/O₂ | X | ◯ (above 2) | ◯ | ◯ | ◯ |
| (4)CF₄/CO₂ | ◯ | ◯ (above 2) | ◯ | ◯ | ◯ |
| (5)CF₄/N₂/CO₂ | ◯ | Δ (1.5˜2) | ◯ | Δ | ◯ |
| (6)CF₄/CHF₃/CO₂ | ◯ | Δ (about 2) | ◯ | ◯ | ◯ |
| (7)CF₄/CH₂F₂/CO₂ | ◯ | Δ (about 2) | ◯ | ◯ | ◯ |
| (8)C₄F₈/CO₂ | ◯ | X (below 1) | ◯ | ◯ | ◯ |
| (9)CH₂F₂/CF₄/Ar/O₂ | X | ◯ (above 2) | ◯ | X | ◯ |
| (10)CH₂F₂/CF₄/Ar/CO₂ | ◯ | ◯ (above 2) | ◯ | X | ◯ |
| (11)CHF₃/CH₂F₂/Ar | ◯ | ◯ (above 2) | X | X | ◯ |
| (12)NF₃/Ar | X | ⊚ (above 3) | ◯ | X | X |
| (13)NF₃/He/Ar | X | ⊚ (above 3) | ◯ | X | X |
| (14)NF₃/Ar/CO | X | ⊚ (above 3) | ◯ | X | ◯ |

Gas flow rates in the tests (1) to (14) in Table 1 are set as follows:

(1) CF₄=150 mL/min (scam)

(2) CF₄/N₂=150/50 mL/min (scam);

(3) CF₄/O₂=150/15 mL/min (scam);

(4) CF₄/CO₂=300/100 mL/min (scam)

(5) CF₄/N₂/CO₂=300/50/100 mL/min (scam)

(6) CF₄/CHF₃/CO₂=150/50/100 mL/min (scam)

(7) CF₄/CH₂F₂/CO₂=150/15/100 mL/min (scam)

(8) C₄F₈/CO₂=30/50 mL/min (scam);

(9) CH₂F₂/CF₄/Ar/O₂=15/60/450/30 mL/min (scam)

(10) CH₂F₂/CF₄/Ar/CO₂=15/60/450/100 mL/min (scam)

(11) CHF₃/CH₂F₂/Ar=80/20/800 mL/min (scam)

(12) NF₃/Ar=8/200 mL/min (scam);

(13) NF₃/He/Ar=8/100/200 mL/min (scam); and

(14) NF₃/Ar/CO=8/200/50 mL/min (scam).

As common conditions of the tests (1) to (14), a pressure inside the chamber 2 was set to be 6.7 Pa (50 mTorr) and, also, high frequency powers of 400 W and 100 W were supplied to the upper electrode 21 and the susceptor 5 as the lower electrode, respectively. Accordingly, the etching gases were converted into the plasma, thereby performing the etching. At this time, the back pressure was set to be 2000 Pa (15 Torr)/5333 Pa (40 Torr) at center portion/edge portion of the wafer W. Further, the processing temperature was set to be 60° C. on a sidewall of the chamber 2 and 20° C. at the susceptor 5. An etching time was set depending on the tests.

The etching characteristics were determined based on evaluation criteria as follows. Herein, the etching characteristics include the damage of the porous Low-k film 104, the selectivity to the hard mask film (TEOS-SiO₂) 106, the effects of suppressing deposition of polymer, the surface roughness of the porous Low-k film 104 exposed in the recesses 210 and the side etching.

<Damage of the Porous Low-k Film>

After the etching process, the wafer W was treated by a hydrofluoric acid (HF) and changes in CDs (Critical Dimensions) of the recesses were measured. From the fact that a surface of the porous Low-k film 104 is oxidized if a plasma damage occurs thereat, the oxide film is removed by the hydrofluoric acid treatment, which makes the CDs changed. In the tests, if the percentage of CD variation exceeds 7%, it is determined that damage occurs. Damage occurrence cases were indicated as x (bad), whereas non-damage cases were indicated as o (good). Moreover, the CD variation percentage of 7% corresponds to 6 mm as a value of CD variation, i.e., (a CD value obtained after the hydrofluoric acid treatment)—(a CD value obtained before the hydrofluoric acid treatment).

<Etching Selectivity to Hard Mask (SiO₂)>

A ratio of ER₁/ER₂ was obtained from an etching rate ER₁ of the stopper film 102 and an etching rate ER₂ of the hard mask film 106. A ratio of about 1 or less was evaluated as “x” (bad); a ratio ranging from above 1 to 2 was evaluated as “Δ” (normal); a ratio ranging from above 2 to 3 was evaluated as “o” (good); and a ratio of above 3 was evaluated as “⊚” (best).

<Polymer (Deposit) Suppressing Effect>

A noticeable adhesion of polymer was evaluated as “x” (bad), whereas an unnoticeable adhesion thereof was evaluated as “o” (good).

<Surface Roughness of Porous Low-k Film>

A remarkable surface roughness of the porous Low-k film 104 exposed in the recess was evaluated as “x” (bad); a slight surface roughness thereof was evaluated as “Δ” (normal); and an unnoticeable surface roughness thereof was evaluated as “o” (good).

<Side Etching>

An occurrence of a side etching of the stopper film 102 in the recess 210 was evaluated as “x” (bad), whereas an unnoticeable occurrence of the side etching was evaluated as “o” (good).

As can be seen from the aforementioned evaluations of the etching characteristics (the results shown in Table 1), in the test (1) using only CF₄ gas and the test (2) using CF₄/N₂ gas, the etching selectivity was hardly obtained and a large amount of polymer was adhered on the sidewall of the porous Low-k film 104 in the recess 210. Although the adhesion of polymer was not recognized in the test (3) using CF₄/O₂ gas, a remarkable damage was inflicted on the porous Low-k film 104.

The tests (6) and (7) in which a fluorocarbon gas (CF₄) and CO₂ are combined with a hydrofluorocarbon gas (CHF₃ and CH₂F₂) tends to show a decrease in the etching selectivity to the hard mask film 106.

Even in a case where a fluorocarbon gas and CO₂ are combined, in the test (8) wherein there was used a fluorocarbon compound gas C₄F₈ containing a large number of carbons, the selectivity to the hard mask film 106 was remarkably deteriorated.

In the tests (9) to (14) using the processing gas containing Ar, the etching selectivity to the hard mask film increased. However, there were observed the damage and/or the surface roughness of the porous Low-k film 104. This is believed because the processing gas containing Ar facilitates an ion sputtering operation. Hence, Ar is not suitable for etching an interlayer insulating film having the porous Low-k film 104.

Meanwhile, in the test (4) using the processing gas only containing CO₂ and CF₄ which is a fluorocarbon gas having a small number of carbons, there was exclusively obtained a satisfactory result in every test items, i.e., the damage of the porous Low-k film 104, the etching selectivity to the hard mask film 106, the suppressing effect of polymer adhesion, the surface roughness of the porous Low-k film 104 exposed in the recess 210 and the side etching. Further, in the test (5) using a processing gas containing CF₄ as a fluorocarbon gas having a small number of carbons, CO₂ and N₂, there was obtained a slightly unsatisfactory result in the etching selectivity to the hard mask film 106 and the surface roughness of the porous Low-k film. However, compared with the test (2) using CF₄/N₂, in the test (5), the etching selectivity was improved and the suppressing effect of polymer adhesion was significantly enhanced. As a result, it was confirmed that the etching characteristics can be improved by using CF₄/N₂/CO₂ than by using CF₄/N₂.

The present invention can be modified without being limited to the aforementioned embodiments.

For example, although a capacitively coupled parallel plate type etching apparatus was used in the aforementioned embodiments, it is possible to use various plasma processing apparatuses such as an inductively coupled apparatus and the like as long as the plasma can be produced from the gas species of the present invention.

While the invention has been shown and described with respect to the preferred embodiments, it will be understood by those skilled in the art that various changes and modification may be made without departing from the scope of the invention as defined in the following claims.

What is claimed is:

1. A plasma etching method for etching a target object by using a plasma of a processing gas in a processing chamber of a plasma processing apparatus, wherein:
the target object includes an etching target film and a porous Low-k film formed above the etching target film; and
the processing gas contains CO₂ and a fluorocarbon compound made up of fluorine and carbon in which the number of carbon atom is 2 or less in a molecule, but does not contains a hydrofluorocarbon compound made up of carbon, fluorine and hydrogen.

2. The method of claim 1, wherein the fluorocarbon compound is CF₄.

3. The method of claim 1, wherein a flow rate ratio of the fluorocarbon compound and CO₂ ranges from 3:1 to 10:1.

4. The method of claim 1, wherein the porous Low-k film is an inorganic Low-k film having a dielectric constant of 2.0 to 2.7.

5. The method of claim 1, wherein the target etching film is etched by using as a mask the hard mask film formed above the porous Low-k film.

6. The method of claim 5, wherein the target etching film is a silicon nitride film or a silicon carbide film.

7. The method of claim 6, wherein the hard mask film is a silicon oxide film.

8. The method of claim 5, wherein an etching selectivity of the target etching film to the hard mask film is greater than two.

9. The method of claim 8, wherein an adhesion film is formed between the target etching film and the porous Low-k film and also between the porous Low-k film and the hard mask film.

10. A computer-executable program for controlling a plasma processing apparatus to perform the plasma etching method described in claim 1.

11. A computer readable storage medium for storing therein a computer-executable program, wherein the program controls a plasma processing apparatus to perform the plasma etching method described in claim 1.
